(19) United States
(12) Patent Application Publication
(10) Pub. No.: US 2013/0015546 A1
(43) Pub. Date: Jan. 17, 2013

(54) MULTI-LAYER PHOTOELECTRIC INTEGRATED CIRCUIT DEVICE WITH OVERLAPPING DEVICES

(71) Applicants: In-sung Joe, Seoul (KR); Sung-dong Suh, Seoul (KR); Kyoung-won Na, Seoul (KR); Kyoung-ho Ha, Seoul (KR); Seong-gu Kim, Pyeongtaek-si (KR); Young-hwack Shin, Yeonsu-gu (KR)

(72) Inventors: In-sung Joe, Seoul (KR); Sung-dong Suh, Seoul (KR); Kyoung-won Na, Seoul (KR); Kyoung-ho Ha, Seoul (KR); Seong-gu Kim, Pyeongtaek-si (KR); Young-hwack Shin, Yeonsu-gu (KR)

(73) Assignee: Samsung Electronics Co., Ltd.

(21) Appl. No.: 13/546,363

(22) Filed: Jul. 11, 2012

(30) Foreign Application Priority Data
Jul. 12, 2011 (KR) 10-2011-0068966

(51) Int. Cl. H01L 31/0232; H01L 31/02

(52) U.S. Cl. 257/432; 257/443; 257/E31.127; 257/E31.11

(57) ABSTRACT

An integrated circuit device includes a plurality of device layers disposed on a substrate. A first one of the device layers includes at least one photo device and/or at least one electronic device and a second one of the device layers includes at least one photo device overlying the at least one photo device and/or the at least one electronic device of the first one of the device layers.

### CROSS-REFERENCE TO RELATED APPLICATIONS

This application claims the benefit of Korean Patent Application No. 10-2011-0068966, filed on Jul. 12, 2011, in the Korean Intellectual Property Office, the disclosure of which is incorporated herein in its entirety by reference.

### BACKGROUND

The inventive subject matter relates to integrated circuit devices and, more particularly, to photoelectric integrated circuit devices.

A photoelectric integrated circuit is an integrated circuit including at least one photo device and at least one electronic device integrated in a common microelectronic structure. In a typically photoelectric integrated circuit device, a photo device and an electronic device are formed laterally adjacent on a semiconductor substrate. Because the photo device may be relatively large, chip area may be mostly occupied by the photo device. It may be costly to produce such photoelectric integrated circuit devices.

### SUMMARY

In some embodiments of the inventive subject matter, an integrated circuit device includes a substrate, a first device layer disposed on the substrate and including at least one first photo device and a second device layer disposed on the first device layer and including at least one second photo device. The integrated circuit device may further include a first insulating layer disposed between the substrate and the first device layer, a second insulating layer disposed between the first device layer and the second device layer and a third insulating layer disposed on the second device layer. The first insulating layer and the second insulating layer may function as a cladding for the at least one first photo device and the second insulating layer and the third insulating layer may function as a cladding for the at least one second photo device.

In some embodiments, the at least one first photo device includes a first photo-communication device and the at least one second photo device includes a second photo-communication device configured to communicate with the first photo-communication device. The first photo-communication device and the second photo-communication devices may be configured to communicate photo signals along a direction perpendicular to the substrate.

In some embodiments, the integrated circuit may further include a waveguide disposed between the first photo-communication device and the second photo-communication device and configured to communicate photo signals between the first photo-communication device and the second photo-communication device along a direction perpendicular to the substrate.

In some embodiments, the second device layer includes at least one third photo-communication device configured to communicate photo signals outside of the device and the integrated circuit device further includes a waveguide configured to support communication between the third photo-communication device and the second photo-communication device. The third photo-communication device may include a grating coupler disposed at an end of the waveguide, a mirror structure disposed at the end of the waveguide and/or a butt-coupler that directly connects the end of the waveguide and a photo fiber.

In some embodiments, the at least one first photo device may include a first grating coupler. The at least one second photo device may include a second grating coupler configured to communicate with the first grating coupler. The first and second grating couplers may be configured to communicate along a direction perpendicular to the substrate.

In some embodiments, the first device layer may further include at least one electronic device that is electrically connected to the at least one first photo device or the at least one second photo device.

According to additional embodiments of the inventive subject matter, an integrated circuit device includes a substrate, a first device layer disposed on the substrate and including at least one electronic device and a second device layer disposed on the first device layer and including at least one photo device.

The integrated circuit device may further include a first insulating layer disposed between the first device layer and the second device layer, a second insulating layer disposed on the second device layer and at least one interconnection line disposed in at least one of the first insulating layer and the second insulating layer and electrically connected to the at least one electronic device. The first insulating layer and the second insulating layer may function as a cladding for the at least one photo device. The first device layer may further include at least one photo device configured to communicate with the at least one photo device of the second device layer. A device isolation layer may be disposed between the at least one electronic device of the first device layer and at least one photo device of the first device layer.

In some embodiments of the inventive subject matter, an integrated circuit device includes a plurality of device layers disposed on a substrate. A first one of the device layers includes at least one photo device and/or at least one electronic device and a second one of the device layers includes at least one photo device overlying the at least one photo device and/or the at least one electronic device of the first one of the device layers. In some embodiments, the at least one photo device and/or the at least one electronic device of the first one of the device layers may be electrically coupled and/or photocoupled to the at least one photo device of the second one of the device layers.

The integrated circuit device may further include at least one insulating layer disposed adjacent at least one of the first and second ones of the device layers and configured to serve as a cladding for the at least one photo device of the first one of the device layers and/or the at least one photo device of the second one of the device layers.

In some embodiments, the first and second ones of the device layers include respective grating couplers or respective mirrors configured to communicate with one another. In some embodiments, the integrated circuit device may further include a waveguide configured to support communications between respective first and second photo devices in the first and second ones of the device layers.

### BRIEF DESCRIPTION OF THE DRAWINGS

Exemplary embodiments of the inventive subject matter will be more clearly understood from the following detailed description taken in conjunction with the accompanying drawings in which:

FIG. 1A is a schematic cross-sectional view of a semiconductor device according to some embodiments of the inventive subject matter;

FIG. 1B is a schematic cross-sectional view of a semiconductor device according to some embodiments of the inventive subject matter;

FIG. 2 is a schematic cross-sectional view of a semiconductor device according to some embodiments of the inventive subject matter;

FIG. 3 is a schematic cross-sectional view of a semiconductor device according to some embodiments of the inventive subject matter;

FIG. 4A is a schematic cross-sectional view of a semiconductor device according to some embodiments of the inventive subject matter;

FIG. 4B is a schematic cross-sectional view of a semiconductor device according to some embodiments of the inventive subject matter;

FIG. 5 is a schematic cross-sectional view of a semiconductor device according to some embodiments of the inventive subject matter; and

FIG. 6 is a schematic cross-sectional view of a semiconductor device according to some embodiments of the inventive subject matter.

### DETAILED DESCRIPTION

Hereinafter, embodiments of the inventive subject matter will be described in detail with reference to the attached drawings.

The inventive subject matter may be embodied in many different forms and should not be construed as being limited to the embodiments set forth herein; rather, these embodiments are provided so that this disclosure will be thorough and complete, and will fully convey the inventive subject matter to those of ordinary skill in the art.

It will be understood that when an element or layer is referred to as being “on” another element or layer, the element or layer can be directly on another element or layer or intervening elements or layers. Like numbers refer to like elements throughout. As used herein, the term “and/or” includes any and all combinations of one or more of the associated listed items.

The terms used herein are used to describe exemplary embodiments and are not intended to limit the inventive subject matter. The use of the terms “a” and “an” and “the” and similar referents in the context of describing the invention are to be construed to cover both the singular and the plural. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc., may be used herein to describe various elements, components, areas, layers and/or sections, these elements, components, areas, layers and/or sections should not be limited by these terms. These terms are only used to distinguish one element, component, area, layer or section from another area, layer or section. Thus, a first element, component, area, layer or section discussed below could be termed a second element, component, area, layer or section without departing from the teachings of the inventive subject matter.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of areas illustrated herein but are to include deviations in shapes that result, for example, from manufacturing.

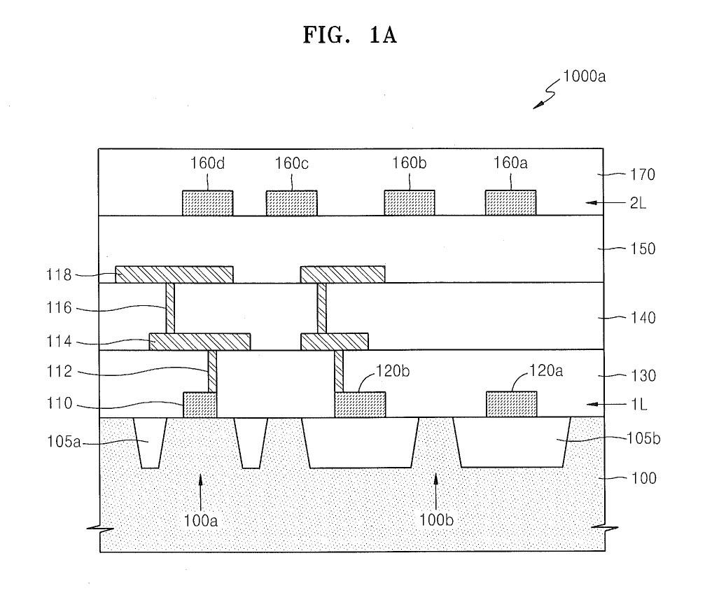

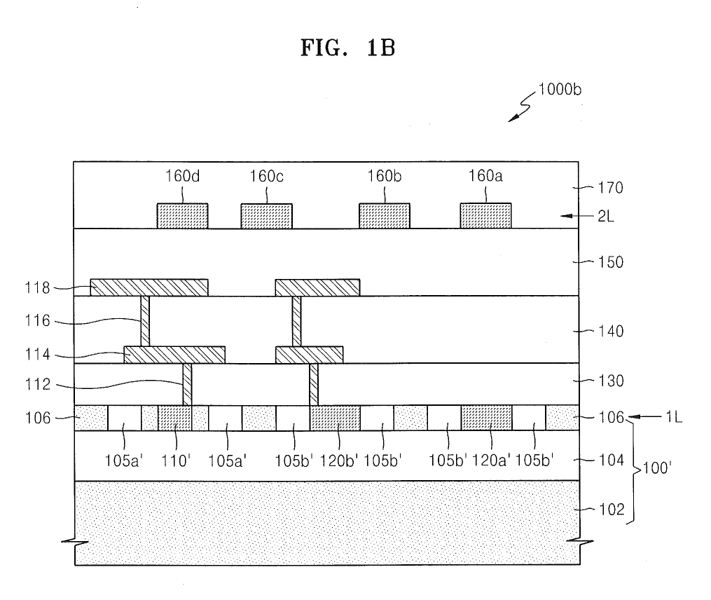

FIG. 1A is a schematic view of a semiconductor device 1000a according to some embodiments of the inventive subject matter.

Referring to FIG. 1A, the semiconductor device 1000a includes a substrate 100, an electronic device 110 and photo devices 120a and 120b disposed on the substrate 100, and photo devices 160a, 160b, 160c, and 160d disposed on the electronic device 110 and the photo devices 120a and 120b.

The substrate 100 may be a semiconductor substrate, in particular, a conventional substrate having a planar upper surface, such as a bulk silicon substrate. In some embodiments, the substrate 100 may be a compound semiconductor substrate, such as a silicon-on-insulator (SOI) substrate, a silicon-germanium substrate, a silicon-carbide substrate, or a gallium-arsenic substrate.

Device isolation layers 105a and 105b may be disposed on an upper surface of the substrate 100. The device isolation layer 105a may define a first area of the substrate 100, on which the electronic device 110 is disposed. The device isolation layer 105a may be used to electrically insulate the electronic devices 110 from each other.

The device isolation layer 105b may be disposed in a second area of the substrate 100 on which the photo devices 120a and 120b are disposed. The photo devices 120a and 120b may be disposed on the device isolation layer 105b. The device isolation layer 105b may function as a lower cladding for the photo devices 120a and 120b.

The device isolation layers 105a and 105b may be simultaneously formed. For example, the device isolation layers 105a and 105b may be formed by filling a trench (not shown) formed in the upper surface of the substrate 100 with an insulating material. The insulating material may include, for example, silicon oxide, silicon oxynitride, and/or silicon nitride.

Although not illustrated in FIG. 1A, trenches corresponding to the device isolation layers 105b may be alternately filled with an insulating material and a semiconductor material, such as amorphous silicon or polysilicon. In this case, the semiconductor material may function as a reflection layer.

In FIG. 1A, an upper surface of the device isolation layer 105b is flush with the upper surface of the substrate 100. However, the upper surface of the device isolation layer 105b may lie at a lower level than the upper surface of the substrate 100. Since a width of the device isolation layer 105b is greater than a width of the device isolation layer 105a, even when the trench of the device isolation layer 105a is completely filled with an insulating material, the trench of the device isolation layer 105b may not completely filled with the insulating material. As described above, when a space formed due to the incomplete filling of the trenches with the insulating material is filled with a semiconductor material, the photo devices 120a and 120b may be formed using the semiconductor material.

The electronic device 110 may be disposed on the first area between the device isolation layers 105a of the substrate 100. The electronic device 110 may include, for example, an individual semiconductor device, such as a transistor and a diode. The electronic device 110 may include an integrated circuit (IC), a microprocessor, a memory, or a highly integrated circuit (LSI). In particular, the electronic device 110 may include a circuit configured to interoperate with the photo devices 120a and 120b, 160a, 160b, 160c, and 160d. The electronic device 110 may be formed using a typical semiconductor process.

The photo devices 120a and 120b may be disposed on the device isolation layers 105b. The photo devices 120a and 120b may include active photo devices and/or passive photo devices. The photo devices 120a and 120b may include, for example, a light source, a modulator, a receiver or other active photo device to which an electric power is supplied. The photo devices 120a and 120b may also include passive photo devices, such as a waveguide, a coupler, a filter, and/or a multiplexer, to which electric power is not supplied.

In FIG. 1A, an interconnection line is connected to only the photo device 120b, not to the photo device 120a. The photo device 120b may be an active photo device and the photo device 120a may be a passive photo device. However, the interconnection line connected to the photo device 120b is exemplary and embodiments of the inventive subject matter are not limited to the structure illustrated in FIG. 1A.

The photo devices 120a and 120b may each include a semiconductor material. For example, the photo devices 120a and 120b may each include a silicon material, such as amorphous silicon, polysilicon, or mono-crystalline silicon.

For example, to fabricate the photo devices 120a and 120b including mono-crystalline silicon, amorphous silicon or polysilicon may be deposited on the device isolation layers 105b by using a semiconductor process, such as chemical vapor deposition (CVD). The amorphous silicon or polysilicon may be crystallized by solid phase epitaxial (SPE) growth or laser epitaxial growth (LEG) to form mono-crystalline silicon. The mono-crystalline silicon may be patterned using a photolithography process and an etching process to form the photo devices 120a and 120b.

Although FIG. 1 illustrates only two photo devices 120a and 120b disposed on the substrate 100, the illustrated structure is exemplary, and three or more photo devices may be disposed on the substrate 100 in some embodiments. Although the photo devices 120a and 120b illustrated in FIG. 1 are not connected to each other, in some embodiments, the photo devices 120a and 120b may be connected to each other via a waveguide disposed on the substrate 100. The photo device 120a may also be connected to an interconnection line.

As illustrated in FIG. 1, the electronic device 110 and the photo devices 120a and 120b may be disposed on the same level on the substrate 100, and may be formed using a semiconductor material that is used to form the substrate 100. Hereinafter, the electronic device 110 and the photo devices 120a and 120b will be referred to as a first device layer 1L. The photo devices 160a through 160d overlying the first device layer 1L will be referred to as a second device layer 2L. The photo devices 120a and 120b included in the first device layer 1L may also be referred to as lower photo devices to distinguish the photo devices 120a and 120b from the photo devices 160a through 160d included in the second device layer 2L. The photo devices 160a through 160d included in the second device layer 2L may be referred to as upper photo devices.

An insulating layer 130 may be disposed on the first device layer 1L. Contact plugs 112 are electrically connected to the electronic device 110 and the photo device 120b through the insulating layer 130. The contact plugs 112 may be formed by forming contact holes (not shown) through the insulating layer 130 and filling the contact holes with a conductive material. The insulating layer 130 may function as an upper cladding for the photo devices 120a and 120b.

Interconnection lines 114 may be disposed on the insulating layer 130 and may be electrically connected to the contact plugs 112. An insulating layer 140 may be disposed on the insulating layer 130, covering the interconnection lines 114. Contact plugs 116 are electrically connected to the interconnection lines 114 through the insulating layer 140.

Interconnection lines 118 may be disposed on the insulating layer 140 and may be electrically connected to the contact plugs 116. An insulating layer 150 may be disposed on the insulating layer 140, covering the interconnection lines 118. The insulating layer 150 may function as a lower cladding for the photo devices 160a through 160d.

Although the insulating layers 130, 140, and 150 illustrated in FIG. 1 are illustrated as distinguished from each other as individual layers, portions of these layers may not be distinguishable in the actual device. The insulating layers 130, 140, and 150 may be formed of the same insulating material. The insulating layers 130, 140, and 150 may each include, for example, silicon oxide, silicon nitride and/or silicon oxynitride.

Although in FIG. 1A, the interconnection line connected to the electronic device 110 is not electrically connected to the interconnection line connected to the photo device 120b, according to a function of the semiconductor device 1000a, the electronic device 110 and the photo device 120b may be electrically connected to each other via interconnection lines.

The photo devices 160a through 160d may be disposed on the insulating layer 150. The photo devices 160a through 160d may include active and/or passive photo devices. For example, the photo devices 160a through 160d may include active devices such as a light source, a modulator, and/or a receiver. An interconnection line and/or contact plug for the connection of the active photo device and the electronic device 110 to an electric power may be present. The photo devices 160a through 160d may include passive devices such as a waveguide, a coupler, a filter, and/or a multiplexer.

The lower photo device 120a and the upper photo device 160d may exchange information using photo signals. For example, one of the lower photo device 120a and the upper photo device 160a may be a light-emission device, while another one may be a light-receiving device. For example, one of the photo device 120a and the upper photo device 160a may be a laser diode for converting an electric signal into a photo signal, and the other one is a photo diode for converting a photo signal into an electric signal. Also, one of the photo device 120a and the upper photo device 160a may be a laser diode, and the other one may be a coupler for receiving a photo signal transmitted from the laser diode. Also, all the lower photo device 120a and the upper photo device 160a may be couplers for transmitting a photo signal. To exchange a photo signal between the lower photo device 120a and the upper photo device 160d, the interconnection lines 114 and 118 may not be located between the lower photo device 120a and the upper photo device 160d. Hereinafter, the lower photo device 120a and the upper photo device 160d, which exchange information each other in the form of a photo signal, may also be referred to as photo communication devices.

The photo devices 160a through 160d may each include a semiconductor material. For example, the photo devices 160a through 160d may each include a silicon material, such as amorphous silicon, polysilicon, or mono-crystalline silicon.

For example, to fabricate the photo devices 160a through 160d including mono-crystalline silicon, amorphous silicon, or polysilicon is deposited on the insulating layer 150 by using a semiconductor process, such as CVD. The amorphous silicon or polysilicon may be crystallized by SPE growth or LEG to form mono-crystalline silicon. The mono-crystalline silicon may be patterned by using a photolithography process and an etching process to form the photo devices 160a through 160d. However, the photo devices 160a through 160d may mostly include amorphous silicon or polysilicon that is deposited by using a low temperature semiconductor process, such as CVD, to not expose the interconnection lines 114 and 118 to a high temperature condition.

An insulating layer 170 may be disposed on the photo devices 160a through 160d, and the insulating layer 170 may function as an upper cladding for the photo devices 160a through 160d. The insulating layer 170 may include, for example, silicon oxide, silicon nitride and/or silicon oxynitride.

A cladding refers to a region covering another region and having a relatively low refractive index. A photo signal transmitted via the core may not be absorbed in the cladding and may be totally reflected. The device isolation layer 105b, the insulating layer 130, the insulating layer 140, the insulating layer 150, and the insulating layer 170 surrounding the photo devices 120a, 120b, and 160a through 160d each including a semiconductor material, for example, silicon, may function as a cladding for the photo devices 120a, 120b, and 160a through 160d. In general, among silicon, silicon nitride, silicon oxynitride, and silicon oxide, silicon has the highest refractive index, and the refractive index decreases in the sequence of silicon nitride, silicon oxynitride, and silicon oxide. Since silicon oxide has the lowest refractive index, silicon oxide may be used in the device isolation layer 105b, and the insulating layers 130, 140, 150, and 170.

The size of a chip may not be increased indefinitely due to factors such as cost and yield for the substrate 100, i.e., the size of the substrate 100 is subject to practical limits. To integrate photo devices and electronic devices together, the limited area of the substrate 100 needs to be effectively used. According to some embodiments of the inventive subject matter, an electronic device or an active photo device using a high-quality semiconductor may be disposed on a lower layer and a passive photo device, such as a waveguide, a coupler, a filter, and a multiplexer, may be disposed on an upper layer. By doing so, the limited area of the substrate 100 may be effectively used. Since a photo signal may pass through an insulating material, for example, silicon oxide, without a substantial loss, a photo device disposed on the lower layer and a photo device disposed on the upper layer may communicate photo signals therebetween. Accordingly, signal connection-related problems between devices disposed on the upper layer and devices disposed on the lower layer may be reduced.

According to some embodiments of the inventive subject matter, the first device layer 1L may include only the electronic device 110 or the photo devices 120a and 120b. That is, according to a function of the semiconductor device 1000a, the electronic device 110 or the lower photo devices 120a and 120b may not be used.

Although in FIG. 1 the first device layer 1L includes the electronic device 110 and the photo devices 120a and 120b and the second device layer 2L includes the photo devices 160a through 160d, the second device layer 2L may further include other photo devices, i.e., the semiconductor device 1000a may include a plurality of photo devices disposed on a plurality of layers.

FIG. 1B is a schematic cross-sectional view of a semiconductor device 1000b according to some embodiments of the inventive subject matter. Referring to FIG. 1B, the semiconductor device 1000b includes a substrate 100′, an electronic device 110′ and photo devices 120a′ and 120b′ disposed on the substrate 100′, and photo devices 160a, 160b, 160c, and 160d disposed on the electronic device 110′ and the photo devices 120a′ and 120b′. The semiconductor device 1000b of FIG. 1B is different from the semiconductor device 1000a of FIG. 1A in that the substrate 100 of the semiconductor device 1000a is a bulk silicon substrate and the substrate 100′ of the semiconductor device 1000b is an SOI substrate. Like reference numerals denote like elements, and elements that have been described with reference to FIG. 1A will not be described in detail herein.

The SOI substrate 100′ includes a lower semiconductor layer 102, an insulating layer 104, and an upper semiconductor layer 106. The lower semiconductor layer 102 and the upper semiconductor layer 106 may include a semiconductor material, for example, mono-crystalline silicon, and the insulating layer 104 may include an insulating material, for example, silicon oxide.

The electronic device 110′ and the photo devices 120a′ and 120b′ may be formed using the upper semiconductor layer 106 and will be referred to as a first device layer 1L. The electronic device 110′ and the photo devices 120a′ and 120b′ respectively correspond to the electronic device 110 and the photo devices 120a and 120b illustrated in FIG. 1A and will not be described in detail herein.

The electronic device 110′ may be surrounded by a device isolation layer 105a′. The device isolation layer 105a′ may define a first area of the substrate 100′, on which the electronic device 110′ is disposed and may include an insulating material. The device isolation layer 105a′ may correspond to the device isolation layer 105a illustrated in FIG. 1.

A cladding layer 105b′ may be disposed surrounding side surfaces of the photo devices 120a′ and 120b′. The cladding layer 105b′ may function as a cladding for the photo devices 120a′ and 120b′ and may be formed of a material that is used to form the device isolation layer 105a′ in a process used to form the device isolation layer 105a′. The cladding layer 105b′ may surround the photo devices 120a′ and 120b′ together with the insulating layer 104 and an insulating layer 130 and may function as a cladding for the photo devices 120a′ and 120b′. The cladding layer 105b′ may include, for example, silicon oxide, silicon oxynitride and/or silicon nitride.

According to some embodiments of the inventive subject matter, a semiconductor device 1000b uses an SOI substrate. By using the SOI substrate, the semiconductor device 1000b may include a high-quality photo device.

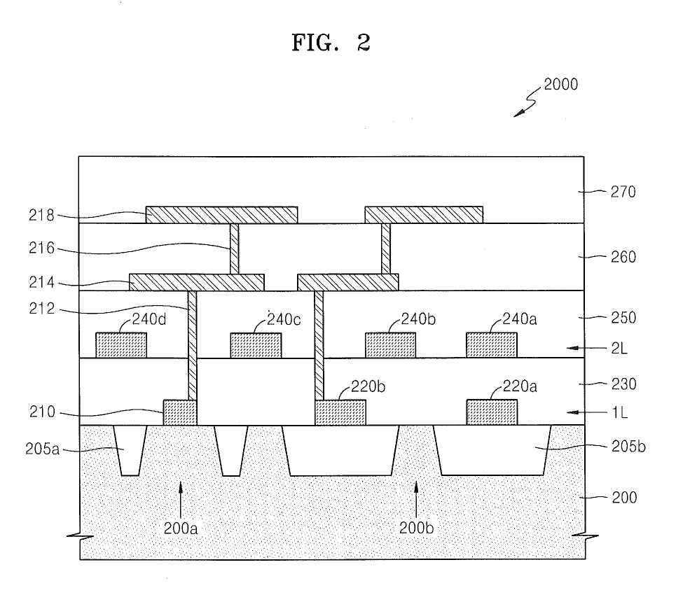

FIG. 2 is a schematic cross-sectional view of a semiconductor device 2000 according to some embodiments of the inventive subject matter. Referring to FIG. 2, the semiconductor device 2000 differs from the semiconductor device 1000a of FIG. 1A in that a second device layer 2L is interposed between a first device layer 1L and insulating layers 260 and 270 respectively including interconnection lines 214 and 218. Herein, only the difference will be described in detail.

As illustrated in FIG. 2, the first device layer 1L may be disposed on a substrate 200 on which device isolation layers 205a and 205b are formed. An insulating layer 230 may be disposed on the first device layer 1L. The second device layer 2L may be disposed on the insulating layer 230. An insulating layer 250 and the insulating layers 260 and 270 may be disposed on the second device layer 2L.

The insulating layer 260 may be disposed covering the interconnection lines 214, and the insulating layer 270 may be disposed covering the interconnection lines 218. Contact plugs 212 may electrically connect an electronic device 210 and a photo device 220b to the interconnection lines 214 through the insulating layers 230 and 250. Contact plugs 216 may electrically connect the interconnection lines 214 to the interconnection lines 218.

Photo devices 240a through 240d included in the second device layer 2L may each include a semiconductor material, for example, mono-crystalline silicon. As illustrated in FIG. 1A, mono-crystalline silicon may be formed by crystallizing amorphous silicon or polysilicon, which is deposited on the insulating layer 150 by using a semiconductor process such as CVD, by using SPE growth or LEG. SPE growth or LEG is a relatively high temperature process compared to CVD. If a conductive material that has a relatively low melting point is used to form contact plugs or interconnection lines and then the SPE growth process or the LEG process is performed thereon, the contact plugs or interconnection lines may melt and thus, reliability-related problems may occur. However, in some embodiments, the contact plugs 212 and 216 and the interconnection lines 214 and 218 are formed after the second device layer 2L is formed, and the photo devices 240a through 240d of the second device layer 2L may include mono-crystalline silicon. Accordingly, the photo devices 240a through 240d may have high quality.

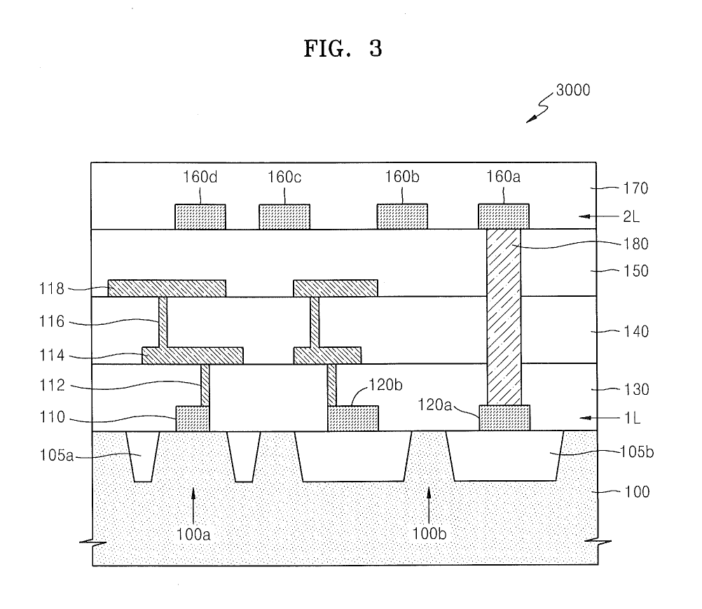

FIG. 3 is a schematic cross-sectional view of a semiconductor device 3000 according to some embodiments of the inventive subject matter. Referring to FIG. 3, the semiconductor device 3000 differs from the semiconductor device 1000a of FIG. 1A in that a vertical waveguide 180 is disposed between a lower photo device 120a and an upper photo device 160a. Like reference numerals denote like elements, and repetitive description of constituting elements that have been described with reference to FIG. 1A will not be provided.

As described above, the lower photo device 120a and the upper photo device 160a may exchange information by using a photo signal. According to some embodiments, the vertical waveguide 180 may be disposed between the lower photo device 120a and the upper photo device 160a to guarantee reliable transmission of a photo signal.

The vertical waveguide 180 uses insulating layers 130, 140, and 150 as a cladding. The vertical waveguide 180 may be formed after the insulating layer 150 is formed. For example, the vertical waveguide 180 may be formed by forming holes (not shown) through the insulating layers 130, 140, and 150 and then filling the holes with a core material. The core material may have a refractive index that is higher than those of materials included in the insulating layers 130, 140, and 150. For example, the core material may include amorphous silicon, polysilicon, silicon nitride and/or silicon oxynitride.

According to some embodiments, due to the formation of the vertical waveguide 180 between the lower photo device 120a and the upper photo device 160a by using a typical semiconductor process including, for example, a photolithography process and an etching process, a highly reliable photo communication between the lower photo device 120a and the upper photo device 160a may be obtainable.

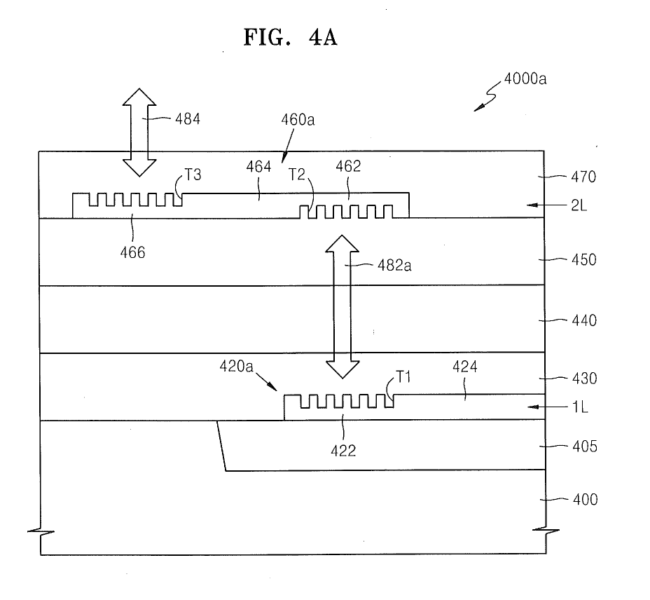

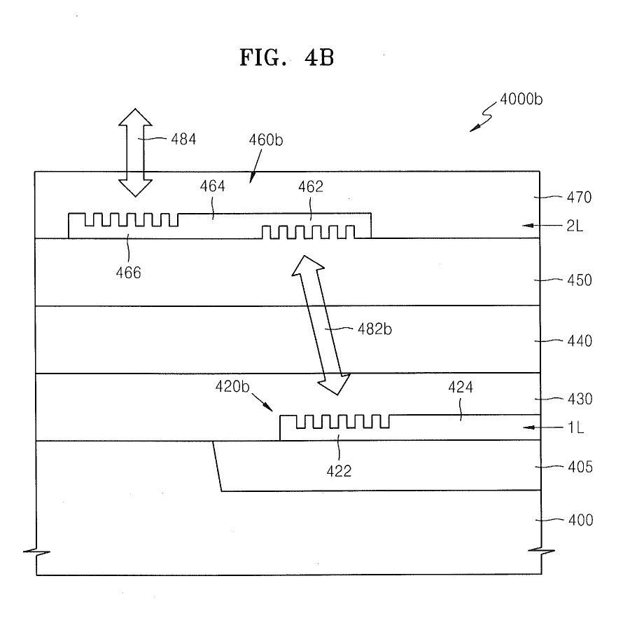

FIG. 4A is a schematic cross-sectional view of a semiconductor device 4000a according to some embodiments of the inventive subject matter. FIG. 4A is a detailed view of the lower photo device 120a and the upper photo device 160a illustrated in FIG. 1A. The other constituent elements illustrated in FIG. 1 A are not illustrated in FIG. 4A to simplify and thus clarify the subject matter illustrated. A lower photo device 420a and an upper photo device 460a illustrated in FIG. 4A is applicable to the semiconductor devices 1000b, 2000, and 3000 of FIGS. 1B, 2, and 3. Descriptions of features already discussed in relation to the semiconductor devices 1000a and 4000a of FIGS. 1A and 4A will not be repeated.

Referring to FIG. 4A, the semiconductor device 4000a may include the lower photo device 420a and the upper photo device 460a, which are disposed on different layers on a substrate 400. A device isolation layer 405 may be disposed on an upper surface of the substrate 400. The lower photo device 420a may be disposed on the device isolation layer 405.

The lower photo device 420a may include a grating coupler 422 and a waveguide 424. The grating coupler 422 may transfer or receive light on such a characteristic basis that light is diffracted when it contacts a lattice structure. Light may be filtered by controlling an interval of the lattice. The waveguide 424 may transfer light that is received by the grating coupler 422 to another photo device (not shown) without light loss.

For example, the grating coupler 422 may include mono-crystalline silicon. A mono-crystalline silicon layer may be formed by depositing amorphous silicon or polysilicon on the device isolation layer 405 and performing an SPE growth process or an LEG process thereon. An upper surface of the mono-crystalline silicon layer may have trenches T1 spaced at constant intervals. Widths and depths of the trenches T may be determined according to a wavelength of light transferred by the grating coupler 422. An insulating layer 430 is formed on the mono-crystalline silicon layer, covering the trenches T, thereby completing the formation of the grating coupler 422. The device isolation layer 405 and the insulating layer 430 may function as a cladding for the grating coupler 422 and the waveguide 424.

Insulating layers 440 and 450 may be disposed on the insulating layer 430. The upper photo device 460a may be disposed on an upper surface of the insulating layer 450.

The upper photo device 460a may include a first grating coupler 462, a waveguide 464, and a second grating coupler 466. The first grating coupler 462 may be formed by forming trenches T2 corresponding to the trenches T1 in the upper surface of the insulating layer 450, and then filling the trenches T2 with a core material, for example, silicon.

The second grating coupler 466 may be used to transmit a photo signal 484 to the outside and to receive the photo signal 484 from an external source. The second grating coupler 466, like the grating coupler 422, may be formed by forming trenches T3 in an upper surface of the upper photo device 460a and filling the trenches T3 with a material that constitutes an insulating layer 470. The insulating layer 470 may cover the upper photo device 460a, and the insulating layers 450 and 470 may function as a cladding for the upper photo device 460a.

The grating coupler 422 may be disposed corresponding and perpendicular to the first grating coupler 462. The grating coupler 422 and the first grating coupler 462 may exchange a photo signal 482a with each other. The second grating coupler 466 may exchange the photo signal 484 with the outside. Accordingly, the photo signal 484 may be transmitted to the waveguide 464 via the second grating coupler 466. The photo signal 484 transmitted to the waveguide 464 may be transmitted in the form of the photo signal 482a to the lower photo device 420a via the first grating coupler 462. The photo signal 482a may be transmitted to the waveguide 424 via the grating coupler 422.

The photo signal 482a transmitted from the lower photo device 420a, in particular, the grating coupler 422, may be transmitted in the form of the photo signal 484 to the outside via the first grating coupler 462, the waveguide 464, and the second grating coupler 466.

To exchange a photo signal with the outside, the second grating coupler 466 may have a larger size than the grating coupler 422 and the first grating coupler 462, which exchange a photo signal with each other inside the semiconductor device 4000a.

In some embodiments, a photo signal may be transmitted or received between the upper photo device 460a and the lower photo device 420a via grating couplers. Since the grating couplers may be fabricated by using common semiconductor processes including, for example, photolithography, etching, and deposition, the grating couplers may be integrated with an electronic device.

FIG. 4B is a schematic cross-sectional view of a semiconductor device 4000b according to some embodiments of the inventive subject matter. Referring to FIG. 4B, the semiconductor device 4000b differs from the semiconductor device 4000a of FIG. 4A in that a lower photo device 420b and an upper photo device 460b, in particular, a grating coupler 422 and a first grating coupler 462, are offset with respect to each other in a horizontal direction. Like reference numerals denote like elements, and elements that have been described with reference to FIG. 4A will not be described again.

In FIG. 4A, the grating coupler 422 of the lower photo device 420a and the first grating coupler 462 of the upper photo device 460a are directly opposed to one another and, therefore, the photo signal 482a is transmitted in a direction perpendicular to the substrate. However, in FIG. 4B, the grating coupler 422 of the lower photo device 420b is disposed offset with respect to the first grating coupler 462 of the upper photo device 460b in the horizontal direction, and thus, a photo signal 482b may be transmitted at an angle from the perpendicular direction. For example, the photo signal 482b may be transmitted at about 5° to about 10° from the perpendicular direction.

As illustrated in FIG. 4B, since the photo signal 482b is transmitted at an angle offset from the perpendicular direction, less distortion caused by reflection may occur. For example, the photo signal 482b transmitted by the first grating coupler 462 may not be completely received by the grating coupler 422, that is, some of the photo signal 482b may be reflected. The reflected photo signal may be received by the first grating coupler 462, thereby causing distortion in transmitting the photo signal 482b. However, as illustrated in FIG. 4B, since the photo signal 482b is transmitted at an angle offset from the perpendicular direction, even when the photo signal 482b is reflected by the grating coupler 422, only some of the reflected photo signal may be received by the first grating coupler 462. Accordingly, distortion of the photo signal 482b caused by reflection may be reduced.

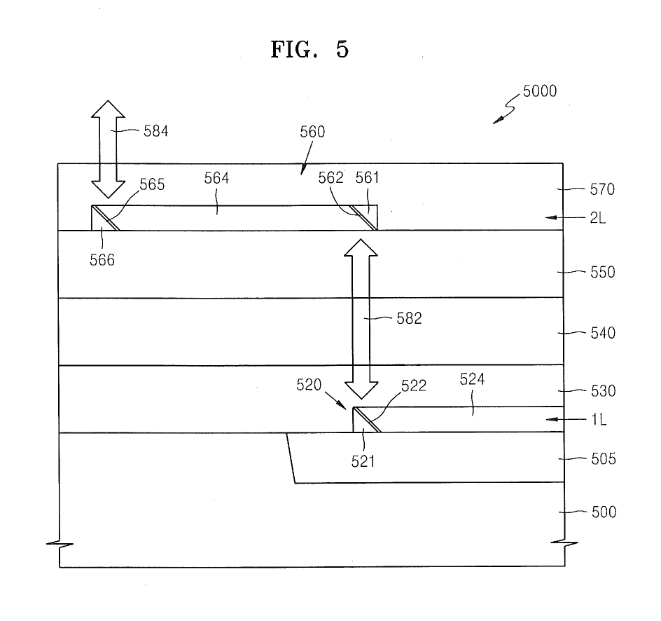

FIG. 5 is a schematic cross-sectional view of a semiconductor device 5000 according to some embodiments of the inventive subject matter. The semiconductor device 5000 has the same structure as the semiconductor device 4000a of FIG. 4A, except for the structures of a lower photo device 520 and an upper photo device 560. Descriptions of items previously described with reference to the semiconductor devices 4000a and 5000 of FIGS. 4A and 5 will not be repeated.

Referring to FIG. 5, the semiconductor device 5000 may include the lower photo device 520 and the upper photo device 560 disposed on different layers on a substrate 500. The lower photo device 520 may include a reflection mirror 521 and a waveguide 524. The reflection mirror 521 may deflect light progressing horizontally in a perpendicular direction such that it is directed vertically, or may deflect light progressing vertically in a perpendicular direction such that it is directed horizontally. The waveguide 524 is connected to the reflection mirror 521, and guides light horizontally toward the reflection mirror 521 and guides light that is reflected by the reflection mirror 521 toward another photo device (not shown) with negligible loss.

The reflection mirror 521 may be formed of a material that has a smaller refractive index than the waveguide 524. The reflection mirror 521 may be formed of, for example, silicon oxide. A silicon oxide layer is deposited on a device isolation layer 505, and a perpendicular surface is formed by perpendicular etching, and a slanted surface is formed by slanted etching. A metal layer 522 may be further formed on the slanted surface. Thereafter, a high refractive index material layer for forming the waveguide 524 is formed thereon and semiconductor processes including, for example, photolithography and etching, may be performed thereon to form the waveguide 524.

The device isolation layer 505 and an insulating layer 530 may function as a cladding for the waveguide 524.

The upper photo device 560 may be disposed on the insulating layer 530, and insulating layers 540 and 550, and may include a first reflection mirror 561, a waveguide 564, and a second reflection mirror 566. The first reflection mirror 561 and the second reflection mirror 566 may be formed by perpendicular etching and slanted etching. Metal layers 562 and 564 may be respectively formed on slanted surfaces of the first and second reflection mirrors 561 and 566. The insulating layer 550 and an insulating layer 570 may function as a cladding for the waveguide 524.

The reflection mirror 521 and the first reflection mirror 561 may be disposed directly opposing one another and may exchange a photo signal 582. The second reflection mirror 566 may exchange a photo signal 584 with an external device.

Accordingly, the photo signal 584 received from the outside may be transmitted in the form of a photo signal 582 to the lower photo device 520 via the second reflection mirror 566, the waveguide 564, and the first reflection mirror 561. The photo signal 582 transmitted via the first reflection mirror 561 may be transmitted to other photo devices included in the lower photo device 520 via the reflection mirror 521 and the waveguide 524. The photo signal 582 transmitted by the lower photo device 520, in particular, the reflection mirror 521, may be transmitted in the form of the photo signal 584 via the first reflection mirror 561, the waveguide 564, and the second reflection mirror 566.

In some embodiments, the upper photo device 560 and the lower photo device 520 may exchange a photo signal via reflection mirrors. Since the reflection mirrors may be formed using common semiconductor processes including, for example, photolithography, etching, and deposition, the reflection mirrors may be integrated together with an electronic device.

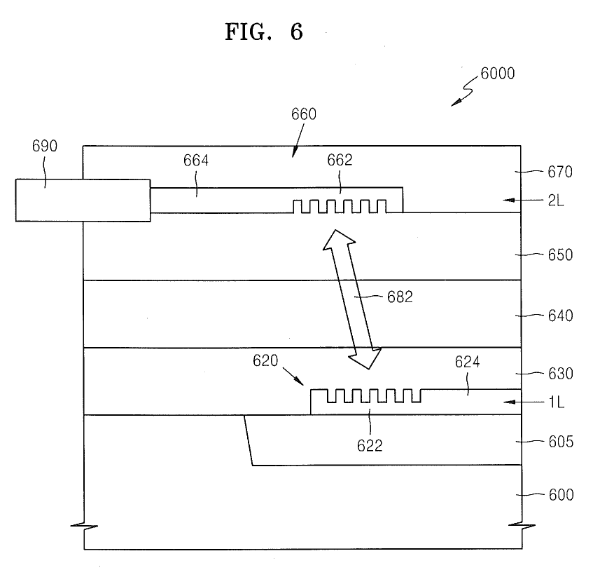

FIG. 6 is a schematic cross-sectional view of a semiconductor device 6000 according to some embodiments of the inventive subject matter. The semiconductor device 6000 has the same structure as the semiconductor device 1000b of FIG. 4B, except for the structure of an upper photo device 660. Descriptions of features shared by the semiconductor devices 4000b and 6000 of FIGS. 4B and 6 will not be repeated.

Referring to FIG. 6, the semiconductor device 6000 may include a lower photo device 620 and the upper photo device 660 disposed on different layers on a substrate 600. The lower photo device 620 may include a grating coupler 622 and a waveguide 624. The upper photo device 660 may include a grating coupler 662, a waveguide 624, and a butt coupler 690.

Since the lower photo device 620, and the grating coupler 662 and a waveguide 664 of the upper photo device 660 substantially correspond to the lower photo device 420b, and the first grating coupler 462 and the waveguide 464 of the upper photo device 460b illustrated in FIG. 4B, description thereof will not be repeated.

The butt coupler 690 may enable a photo connection between the upper photo device 660, in particular, the waveguide 664, and a photo fiber. Since the butt coupler 690 has a direct connection with the waveguide 664, the photo fiber may be directly electrically connected to a side surface of the semiconductor device 6000 via the butt coupler 690.

While the inventive subject matter has been particularly shown, and described with reference to exemplary embodiments thereof, it will be understood that various changes in form, and details may be made therein without departing from the spirit, and scope of the following claims.

What is claimed is:

1. An integrated circuit device comprising:
a substrate;
a first device layer disposed on the substrate and comprising at least one first photo device; and
a second device layer disposed on the first device layer and comprising at least one second photo device.

2. The integrated circuit device of claim 1, further comprising:
a first insulating layer disposed between the substrate and the first device layer;
a second insulating layer disposed between the first device layer and the second device layer; and
a third insulating layer disposed on the second device layer,
wherein the first insulating layer and the second insulating layer function as a cladding for the at least one first photo device, and
wherein the second insulating layer and the third insulating layer function as a cladding for the at least one second photo device.

3. The integrated circuit device of claim 1:
wherein the at least one first photo device comprises a first photo-communication device;
wherein the at least one second photo device comprises a second photo-communication device configured to communicate with the first photo-communication device.

4. The integrated circuit device of claim 3, wherein the first photo-communication device and the second photo-communication devices are configured to communicate photo signals along a direction perpendicular to the substrate.

5. The integrated circuit device of claim 3, further comprising a waveguide disposed between the first photo-communication device and the second photo-communication device and configured to communicate photo signals between the first photo-communication device and the second photo-communication device along a direction perpendicular to the substrate.

6. The integrated circuit device of claim 3, wherein the second device layer comprises:
a third photo-communication device configured to communicate photo signals outside of the integrated circuit device; and
a waveguide configured to support communication between the third photo-communication device and the second photo-communication device.

7. The integrated circuit device of claim 6, wherein the third photo-communication device comprises at least one of grating coupler disposed at an end of the waveguide, a mirror structure disposed at the end of the waveguide, and a butt-coupler that directly connects the end of the waveguide and a photo fiber.

8. The integrated circuit device of claim 1:
wherein the at least one first photo device comprises a first grating coupler; and
wherein the at least one second photo device comprises a second grating coupler configured to communicate with the first grating coupler.

9. The integrated circuit device of claim 8, wherein the first and second grating couplers are configured to communicate photo signals along a direction perpendicular to the substrate.

10. The integrated circuit device of claim 1, wherein the first device layer further comprises at least one electronic device electrically connected to the at least one first photo device or the at least one second photo device.

11. An integrated circuit device comprising:
a substrate;
a first device layer disposed on the substrate and comprising at least one electronic device; and
a second device layer disposed on the first device layer and comprising at least one photo device.

12. The integrated circuit device of claim 11, further comprising:
a first insulating layer disposed between the first device layer and the second device layer;
a second insulating layer disposed on the second device layer; and
at least one interconnection line disposed in at least one of the first insulating layer and the second insulating layer and electrically connected to the at least one electronic device.

13. The integrated circuit device of claim 12, wherein the first insulating layer and the second insulating layer function as a cladding for the at least one photo device.

14. The integrated circuit device of claim 11, wherein the first device layer further comprises at least one photo device configured to communicate with the at least one photo device of the second device layer.

15. The integrated circuit device of claim 14, further comprising a device isolation layer disposed between the at least one electronic device of the first device layer and at least one photo device of the first device layer.

16. An integrated circuit device comprising:
a plurality of device layers disposed on a substrate, a first one of the device layers comprising at least one photo device and/or at least one electronic device and a second one of the device layers comprising at least one photo device overlying the at least one photo device and/or the at least one electronic device of the first one of the device layers.

17. The integrated circuit device of claim 16, wherein the at least one photo device and/or the at least one electronic device of the first one of the device layers is electrically and/or optically coupled to the at least one photo device of the second one of the device layers.

18. The integrated circuit device of claim 16, further comprising at least one insulating layer disposed adjacent at least one of the first and second ones of the device layers and configured to serve as a cladding for the at least one photo device of the first one of the device layers and/or the at least one photo device of the second one of the device layers.

19. The integrated circuit device of claim 16, wherein the first and second ones of the device layers comprise respective grating couplers or respective mirrors configured to communicate with one another.

20. The integrated circuit device of claim 16, further comprising a waveguide configured to support communications between respective first and second photo devices in the first and second ones of the device layers.
